(19) United States
(12) Patent Application Publication
(10) Pub. No.: US 2004/0089946 A1
(43) Pub. Date: May 13, 2004

(54) Chip size semiconductor package structure

(75) Inventor: Ying-Nan Wen, Tao-Yuan (TW)

Correspondence Address: Serge J. Hodgson, Gunnison, McKay & Hodgson, L.L.P., Suite 220, 1900 Garden Road, Monterey, CA, 93940, US

(73) Assignee: Amkor Technology, Inc.

(21) Appl. No.: 10/293,126

(22) Filed: Nov. 12, 2002

(51) Int. Cl. H01L 23/48

(52) U.S. Cl. 257/737

(57) ABSTRACT

A chip size package (CSP) structure is disclosed. The CSP package structure utilizes columnar composite bump structures as contact joints to bond to contact pads. The columnar composite bump structures have high melting point bump layers on the contact pads and a low melting point bump layers. The high melting point and low melting point bump layers are formed on under bump metal (UBM) layers by composite plating processes so that both the bump layers need not to be etched and the underlying contact pads will not be damaged.

### BACKGROUND OF THE INVENTION

1. Field of the Invention

The present invention relates to the assembly and packaging of semiconductor devices.

2. Description of the Related Art

Several approaches exist for the first level assembly of a semiconductor chip to a supporting substrate. These approaches include wire-bonding, tape automated bonding (TAB) and flip chip. An encapsulated chip which is equipped with terminals for interconnection to the external world is often referred to as a chip package.

In wire-bonding, the substrate has a top surface with a plurality of electrically conductive contact pads, sometimes called connections pads, disposed in a ring-like pattern. The chip is secured to the top surface of the substrate at the center of the ring-like pattern, so that the chip is surrounded by the contact pads on the substrate. The chip is mounted in a face-up disposition, with the back surface of the chip glued to the top surface of the substrate. The front surface, sometimes called the front face, of the chip faces upward, and fine wires are connected between the contacts, sometimes called chip I/O pads, chip pads, or simply pads, on the front face of the chip and the contact pads on the top surface of the substrate.

Wire-bonding ordinarily can only be employed when the chip I/O pads are distributed along the periphery of the chip and the substrate connection pads surround the chip in a ring-like pattern, sometimes called a ring-like configuration. Furthermore, wire-bonding typically requires a minimum pad size of 75 microns on a side and becomes non-feasible if the relative spacing between the chip pads decreases below 50 microns. With the ever-increasing number of gates in IC chips, the chip I/O pad counts are also increasing.

Distribution of these increasing number of chip I/O pads along the periphery without increasing the Si chip size is posing a big challenge. Distribution of the chip I/O pads on the entire surface of the chip provides a more efficient configuration but wire-bonding cannot be employed for such cases. In addition, a wire bond is associated with a high inductance value. Thus, for circuits, which involve simultaneous switching of a large number of gates, as is the case in present generation of microprocessors, high inductances of the wire bonds lead to a large switching noise.

Wire bonds usually fan out from the chip to the substrate. Therefore, overall package size increases considerably relative to the chip size. Therefore, from the compactness standpoint, too, wire-bonding does not provide an optimal first level assembly process.

TAB requires a flexible tape with metal leads mounted on a polymer film. Usually, the leads fan out from the chip pads to the substrate connection pads. Therefore, the package is considerably larger than the chip.

The flexible tape represents a new layer for interconnection and considerably adds to the cost of the package. This also requires deposition of excess metal in the form of bumps either on the connection regions of the leads or the chip pads. This is an additional process step and require processes similar to those used for IC fabrication such as lithography, etching and likewise. This adds to the cost of the process.

The chips are bonded to a flexible tape which contains metal traces for external connectivity. Bonding a single lead at a time slows down the assembly cycle time considerably, thereby increasing the cycle time and the cost. Therefore, usually all the leads are bonded simultaneously to the chip pads in what is referred as a “gang bonding” process. This requires very tight control of the planarity of the tape leads and the chip pads connection sites. The long TAB leads also have high inductances and therefore lead to large switching noises in fast digital circuits.

### BRIEF SUMMARY OF THE INVENTION

The various embodiments of the present invention provide for a chip size package structure of a semiconductor device. The structure comprises a semiconductor wafer substrate having devices therein and contact pads thereon, a dielectric layer over the semiconductor wafer substrate and exposing the contact pads, under bump metal layers covering portions of each of the contact pads, first conductive bump layers on the under bump metal layers, and second conductive bump layers on the first conductive bump layers.

The present invention is best understood by reference to the following detailed description when read in conjunction with the accompanying drawings.

### BRIEF DESCRIPTION OF THE DRAWINGS

FIG. 1A is a cross section view of a structure illustrating an initial step of fabricating in accordance with one embodiment of the present invention;

FIG. 1B is a cross section view of the structure of FIG. 1A illustrating a subsequent step of fabricating in accordance with one embodiment of the present invention;

FIG. 1C is a cross section view of the structure of FIG. 1B illustrating still a subsequent step of fabricating in accordance with one embodiment of the present invention; and

FIG. 1D is a cross section view of the structure of FIG. 1C illustrating another subsequent step of fabricating in accordance with one embodiment of the present invention.

Common reference numerals are used throughout the drawings and detailed description to indicate like elements.

### DETAILED DESCRIPTION OF THE INVENTION

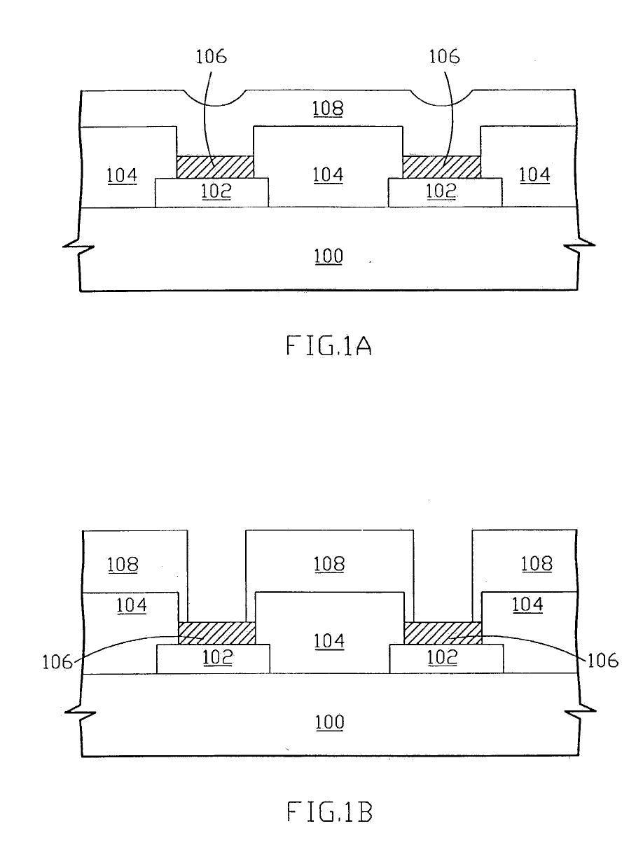

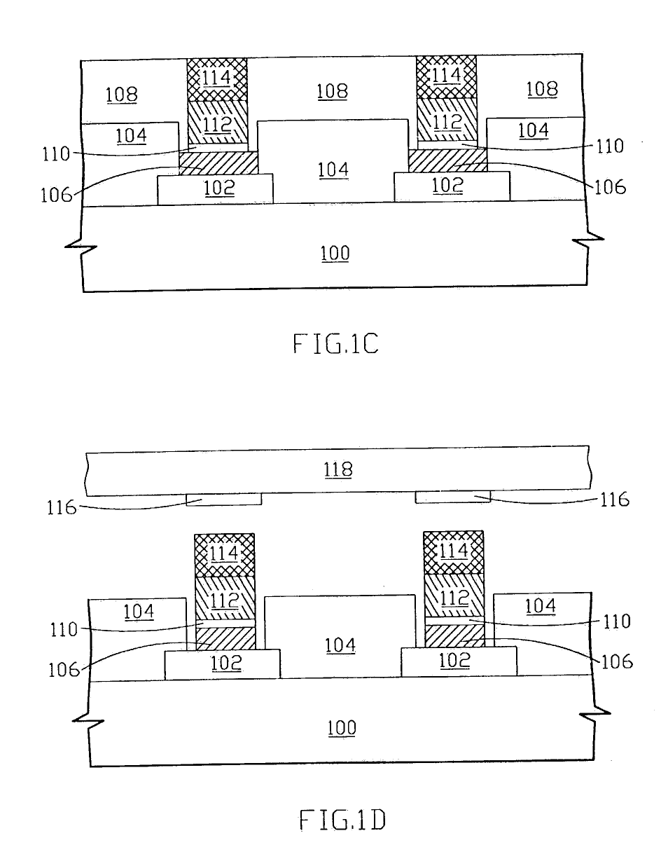

Referring to FIG. 1A, one embodiment of the present invention illustrates a semiconductor wafer substrate 100, sometimes called a semiconductor device, having contact pads 102, a dielectric layer 104, under bump metal (UBM) layers 106 and a photoresist layer 108 thereon.

The semiconductor wafer substrate 100 contains numerous integrated circuit chips therein. The contact pads 102 provide those chips with I/O connections. The contact pads 102 comprise aluminum pads in one embodiment, but other metal pads should not be excluded. The contact pads 102 can be formed by conventional deposition, photolithography and etching processes. The pitch between centers of two adjacent contact pads 102 is about 80 micron in one embodiment.

The dielectric layer 104 comprises a silicon-oxy-nitride (SiON) layer formed by conventional methods. The dielectric layer 104 is patterned and etched by conventional photolithography and etching processes to form openings and expose the contact pads 102. The spacing of two adjacent openings that expose the contact pads 102 can be, for example, about 20 microns.

The UBM layers 106 are formed into the openings and on the exposed contact pads 102. The UBM layers 106 are formed by selective plating processes, e.g., where the UBM layers 106 are plated primarily or only on the exposed contact pads 102. The UBM layers 106 have a width in the range of about 50 to about 60 microns in one embodiment. Then the photoresist layer 108 is formed over the semiconductor wafer substrate 100 by conventional processes.

Referring to FIG. 1B, the photoresist layer 108 is patterned by conventional photolithography processes to form openings and expose portions of the under bump metal layers 106. More particularly, the photoresist layer 108 is patterned to cover first portions, sometimes called covered portions, and to expose second portions, sometimes called exposed portions, of UBM layers 106.

As shown in FIG. 1C, metal layers 110, conductive bump layers 112 and 114 are sequentially formed on the exposed portions of the under bump metal layers 106. The metal layers 110 comprise a nickel layer formed by plating processes in one embodiment, e.g., where nickel is plated on the exposed portions of the UBM layers 106. The thickness of the metal layers 110 can be about 1 micron.

The conductive bump layers 112, sometimes called the first conductive bump layers, comprises a Pb/Sn alloy with a 95/5 eutectic composition in one embodiment. The thickness of the conductive bump layers 112 can be about 5 microns to about 200 microns. The Pb/Sn alloy with a 95/5 eutectic composition can be formed on the metal layers 110 by plating processes. The plating processes comprises composite plating processes. The Pb/Sn alloy with a 95/5 eutectic composition melts above about 310 degrees centigrade.

The conductive bump layers 114, sometimes called the second conductive bump layers, comprises a Pb/Sn alloy with a 63/37 eutectic composition in one embodiment. The thickness of the conductive bump layers 114 can be about 0.5 micron to about 100 microns. The Pb/Sn alloy with a 63/37 eutectic composition can be formed on the conductive bump layers 112 by plating processes. The plating processes comprise composite plating processes. The Pb/Sn alloy with a 63/37 eutectic composition melts above about 260 degrees centigrade.

Referring to FIG. 1D, a chip size package structure in accordance with one embodiment of this invention is shown. The photoresist layer 108 is removed by conventional developing processes. Then an annealing process is performed. In one embodiment, the annealing process is performed at about 183 to about 250 degrees centigrade if the conductive bump layers 112 and 114 are Pb/Sn alloy with a 95/5 eutectic composition and Pb/Sn alloy with a 63/37 eutectic composition, respectively.

The under bump metal layers 106 are etched to expose portions of the contact pads 102 using the metal layers 110, the conductive bump layers 112, 114 as etch masks by conventional etching processes. More particularly, the portions of the UBM layers 106 previously covered by the photoresist layer 108 are removed by etching. Thus, after the etching, the UBM layers 106 cover first portions, sometimes called covered portions, of the contact pads 102 and leave second portions, sometimes called exposed portions, of contact pads 102 exposed. Next the semiconductor wafer substrate 100 is sawed to chip dies and to be assembled. The contact pads 102 of the dies are bonded to metal layers 116 of a substrate 118 through the melt of the conductive bump layers 112 and 114 at a bonding temperature.

A dielectric material comprising an epoxy resin material is then dispensed in the region between the chip die and the substrate 118. This underfill material encapsulates the exposed regions of the metallic joints and acts as a stress buffer thereby significantly improving the reliability. Examples of the substrate 118 include a non-solder-mask-defined (NSMD) substrate as well as a semi-NSMD substrate. The metal layers 116 comprise a NiAu alloy layer in one embodiment.

The various embodiments of the present invention utilize selective plating and composite plating technology to form columnar solder bump structures having a stack of a high melting point solder and a low melting point solder on the contact pads, sometimes called wire bond pads. More particularly, the columnar solder bump structures include the conductive bump layers 112 and the conductive bump layers 114. The columnar solder bump structures provide superior electrical performance since the bump structure are formed directly on the wire bond pads and processes of re-distribution layers (RDL) are not necessary.

Furthermore, due to the process of directly bumping on the wire bond pad, reflow processes of bumping processes can be omitted and the cost of the bumping processes can be reduced. Moreover, a high reliability CSP structure is provided since a fatigue resistance material comprising Pb/Sn alloy with a 95/5 eutectic composition other than conventional copper stud structures is used. Finally, since a NSMD substrate as well as a semi-NSMD substrate are utilized, conventional solder-mask-defined (SMD) substrate and small outline package (SOP) are not necessary and the cost can be further reduced.

This disclosure provides exemplary embodiments of the present invention. The scope of the present invention is not limited by these exemplary embodiments. Numerous variations, whether explicitly provided for by the specification or implied by the specification, such as variations in structure, dimension, type of material and manufacturing process may be implemented by one of skill in the art in view of this disclosure.

What is claimed is:

1. A chip size package structure comprising:
a semiconductor device comprising an integrated circuit therein and contact pads thereon;
a dielectric layer over the semiconductor device and having openings exposing the contact pads;
under bump metal layers covering portions of each of the contact pads;
first conductive bump layers on the under bump metal layers; and
second conductive bump layers on the first conductive bump layers.

2. The chip size package structure according to claim 1, wherein the contact pads comprise aluminum pads.

3. The chip size package structure according to claim 1, wherein the dielectric layer comprises a silicon-oxy-nitride layer.

4. The chip size package structure according to claim 1, wherein the under bump metal layers are formed by selective plating processes.

5. The chip size package structure according to claim 1, wherein the first conductive bump layers comprises a Pb and Sn alloy layer with a 95 to 5 eutectic composition.

6. The chip size package structure according to claim 1, wherein the second conductive bump layers comprises a Pb and Sn alloy layer with a 63 to 37 eutectic composition.

7. The chip size package structure according to claim 1, wherein the under bump metal layers have a width of about 50 microns to about 60 microns.

8. The chip size package structure according to claim 1, wherein the first conductive bump layers have a thickness of about 5 microns to about 200 microns.

9. The chip size package structure according to claim 7, wherein the second conductive bump layers have a thickness of about 0.5 micron to about 100 microns.

10. The chip size package structure according to claim 7, wherein the contact pads comprise two adjacent contact pads, and wherein the pitch between centers of the two adjacent contact pads is about 80 microns.

11. A chip size package structure comprising:
a semiconductor device having an integrated circuit therein and contact pads thereon;
a dielectric layer over the semiconductor device and having openings exposing the contact pads;
under bump metal layers covering portions of each of the contact pads; and
means for bonding the semiconductor device with a substrate through the under bump metal layers, wherein the means for bonding comprises first conductive bump layers and second conductive bump layers.

12. The chip size package structure according to claim 11, wherein the melting temperature of the first conductive bump layers is about 310 degrees centigrade.

13. The chip size package structure according to claim 11, wherein the melting temperature of the second conductive bump layers is about 260 degrees centigrade.

14. A method for forming a chip size package structure comprising:
providing a semiconductor device having contact pads thereon, a dielectric layer covering the semiconductor device and exposing the contact pads, and under bump metal layers on the exposed contact pads;
forming a photoresist layer over the semiconductor device;
patterning the photoresist layer to expose portions of the under bump metal layers;
forming metal layers on the exposed portions of the under bump metal layers;
forming first conductive bump layers on the metal layers;
forming second conductive bump layers on the first conductive bump layers;
removing the photoresist layer; and
etching the under bump metal layers to expose portions of the contact pads.

15. The method according to claim 14, wherein the under bump metal layers are formed by plating on the exposed contact pads.

16. The method according to claim 14, wherein the metal layers are formed by plating on the exposed portions of the under bump metal layers.

17. The method according to claim 14, wherein the first conductive bump layers comprise a Pb/Sn alloy with a 95/5 eutectic composition.

18. The method according to claim 14, wherein the second conductive bump layers comprise a Pb/Sn alloy with a 63/37 eutectic composition.

19. The method according to claim 14 further comprises an annealing process performed after the removing the photoresist layer.

20. The method according to claim 14 further comprising melting the first conductive bump layers and the second conductive bump layers to bond the contact pads to metal layers of a substrate.
